(19) United States
(12) Patent Application Publication
(10) Pub. No.: US 2010/0167212 A1
(43) Pub. Date: Jul. 1, 2010

(54) RESIST UNDERLAYER COMPOSITION AND METHOD OF MANUFACTURING INTEGRATED CIRCUIT DEVICE USING THE SAME

(76) Inventors: Hyeon-Mo Cho, Seoul (KR); Sang-Kyun Kim, Uiwang-si (KR); Mi-Young Kim, Uiwang-si (KR); Sang-Ran Koh, Uiwang-si (KR); Hui-Chang Yun, Uiwang-si (KR); Yong-Jin Chung, Uiwang-si (KR); Jong-Seob Kim, Seoul (KR); In-Sun Jung, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/654,742

(22) Filed: Dec. 30, 2009

(30) Foreign Application Priority Data
Dec. 30, 2008 (KR) 10-2008-0137420

(51) Int. Cl. G03F 7/20; C08L 61/00; C08L 83/00; C08K 5/3432; C08G 77/00

(52) U.S. Cl. 430/313; 525/471; 525/474; 524/99; 528/10

(57) ABSTRACT

A resist underlayer composition and a method of manufacturing a semiconductor integrated circuit device, the resist underlayer composition including a solvent and an organosilane-based polymer, the organosilane-based polymer being a polymerization product of at least one first compound represented Chemical Formulae 1 to 3 and at least one second compound represented by Chemical Formulae 4 and 5.

### BACKGROUND

1. Field

Embodiments relate to a resist underlayer composition and a method of manufacturing integrated circuit devices using the same.

2. Description of the Related Art

In a lithography process, in order to, e.g., minimize reflection between a resist material layer and a substrate and to improve resolution, an anti-reflective coating (ARC) may be used. However, since the anti-reflective coating material may have a basic composition similar to a resist material, the anti-reflective coating material may have a poor etch selectivity with respect to a resist layer with an image imprinted therein. Thus, a patterning process in a subsequent etching process may be required since the resist may also be lost during etching of the ARC.

Also, resist materials may not have sufficient resistance to the subsequent etching process in order to effectively transfer a predetermined pattern to a layer underlying the resist material layer. When a resist layer is thin, when a substrate to be etched is thick, when an etch depth is deep, and/or when a particular etchant is required for a particular substrate, a resist underlayer may be used.

A resist underlayer may act as a interlayer between a patterned resist and a substrate to be patterned. The resist underlayer may transfer a pattern to the substrate. Therefore, it may be desirable for the resist underlayer to withstand etching required to transfer the pattern to the substrate.

### SUMMARY

Embodiments are directed to a resist underlayer composition and a method of manufacturing integrated circuit devices using the same, which represent advances over the related art.

It is a feature of an embodiment to provide a resist underlayer composition, the resist underlayer composition having an absorbance at a wavelength of a 250 nm or less, exhibiting excellent coating without gelling defects, and being capable of transferring a pattern to an underlying material layer due to hardmask properties.

At least one of the above and other features and advantages may be realized by providing a resist underlayer composition including a solvent; and an organosilane-based polymer, the organosilane-based polymer being a polymerization product of at least one first compound represented by Chemical Formulae 1 to 3 and at least one second compound represented by Chemical Formulae 4 and 5,

[R¹]₃Si—(CH₂)ₙR² [Chemical Formula 1]

wherein, in the above Chemical Formula 1 each R¹ is independently a halogen, a hydroxyl group, an alkoxy group, a carboxyl group, an ester group, a cyano group, a haloalkylsulfite group, an alkylamine group, an alkylsilylamine group, or an alkylsilyloxy group, n is 0 to 5, and R² is anthracenyl or naphthyl,

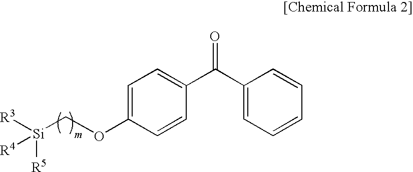

wherein, in the above Chemical Formula 2 R³, R⁴, and R⁵ are each independently a halogen, a hydroxy group, an alkoxy group, a carboxyl group, an ester group, a cyano group, a haloalkylsulfite group, an alkylamine group, an alkylsilylamine group, or an alkylsilyloxy group, and m is 1 to 10,

[R⁶]₃Si—R⁷—Si[R⁶]₃ [Chemical Formula 3]

wherein, in the above Chemical Formula 3 each R⁶ is independently a halogen, a hydroxy group, an alkoxy group, a carboxyl group, an ester group, a cyano group, a haloalkylsulfite group, an alkylamine group, an alkylsilylamine group, or an alkylsilyloxy group, and R⁷ is anthracenylene, naphthalenylene, biphenylene (-Ph-Ph-), terphenylene (-Ph-Ph-Ph-), or quaterphenylene (-Ph-Ph-Ph-Ph-),

[R⁸]₃Si—R⁹ [Chemical Formula 4]

wherein, in the above Chemical Formula 4 each R⁸ is independently a halogen, a hydroxy group, an alkoxy group, a carboxyl group, an ester group, a cyano group, a haloalkylsulfite group, an alkylamine group, an alkylsilylamine group, or an alkylsilyloxy group, and R⁹ is H or a C1 to C6 alkyl group, and

[R¹⁰]₃Si—X—Si[R¹⁰]₃ [Chemical Formula 5]

wherein, in the above Chemical Formula 5 each R¹⁰ is independently a halogen, a hydroxy group, an alkoxy group, a carboxyl group, an ester group, a cyano group, a haloalkylsulfite group, an alkylamine group, an alkylsilylamine group, or an alkylsilyloxy group, X is a substituted or unsubstituted linear alkylene group, a substituted or unsubstituted branched alkylene group, or an alkylene group including an alkenylene group, an alkynylene group, a heterocyclic group, a urea group, or an isocyanurate group in its main chain.

The first compound may be represented by Chemical Formula 2, the first compound represented by Chemical Formula 2 including at least one of 2-hydroxy-4-(3-triethoxysilylpropoxy)diphenylketone, 2-hydroxy-4-(3-trimethoxysilylpropoxy)diphenylketone, and 2-hydroxy-4-(3-trichlorosilylpropoxy)diphenylketone.

The organosilane-based polymer may include a structure represented by Chemical Formula 6 (T1), about 40 mol % to about 80 mol % of a structure represented by Chemical Formula 7 (T2), and a structure represented by Chemical Formula 8 (T3),

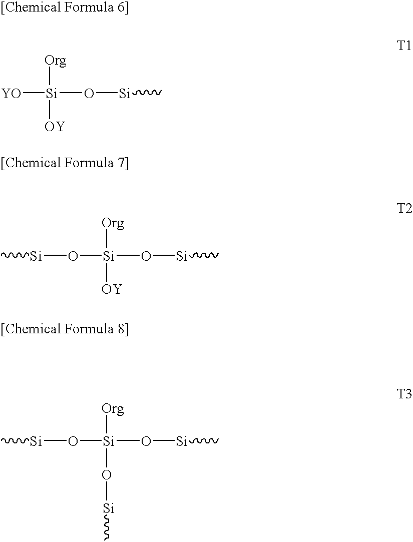

wherein in the above Chemical Formulae 6 and 7, Y is H or a C1 to C6 alkyl group, in the above Chemical Formulae 6, 7, and 8, -Org is —(CH₂)ₙR², a functional group represented by the following Chemical Formula A, —R⁷—Si[R⁶]₃, —R⁹, or —X—Si[R¹⁰]₃, and in Chemical Formulae 6, 7, and 8, R², R⁶, R⁷, R⁹, R¹⁰, and X are the same as in the above Chemical Formulae 1 to 5,

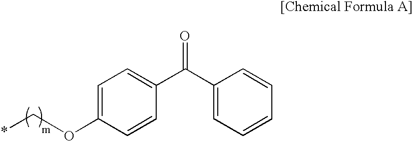

wherein, in the above Chemical Formula A, m is the same as in Chemical Formula 2.

-Org may be the functional group represented by Chemical Formula A.

The organosilane-based polymer may be included in an amount of about 1 to about 50 parts by weight, based on 100 parts by weight of the composition.

The resist underlayer composition may further include at least one of a cross-linking agent, a radical stabilizer, and a surfactant.

The resist underlayer composition may further include at least one of pyridinium p-toluenesulfonate, amidosulfobetain-16, (−)-camphor-10-sulfonic acid ammonium salt, ammonium formate, triethylammonium formate, trimethyammonium formate, tetramethylammonium formate, pyridinium formate, tetrabutylammonium acetate, tetrabutylammonium azide, tetrabutylammonium benzoate, tetrabutylammonium bisulfate, tetrabutylammonium bromide, tetrabutylammonium chloride, tetrabutylammonium cyanide, tetrabutylammonium fluoride, tetrabutylammonium iodide, tetrabutylammonium sulfate, tetrabutylammonium nitrate, tetrabutylammonium nitrite, tetrabutylammonium p-toluenesulfonate, and tetrabutylammonium phosphate.

At least one of the above and other features and advantages may also be realized by providing a method of manufacturing a semiconductor integrated circuit device, the method including providing a material layer on a substrate, forming a first resist underlayer using an organic material on the material layer, coating the aforementioned resist underlayer composition on the first resist underlayer to form a silicon-based second resist underlayer, forming a radiation-sensitive imaging layer on the second resist underlayer, patternwise exposing the radiation-sensitive imaging layer to radiation to form a pattern of radiation-exposed regions in the imaging layer, selectively removing portions of the radiation-sensitive imaging layer and the second resist underlayer to expose portions of the first resist underlayer, selectively removing the patterned second resist underlayer and portions of the first resist underlayer to expose portions of the material layer, and etching the exposed portions of the material layer to pattern the material layer.

The method may further include providing an anti-reflection coating (ARC) between the second resist underlayer and radiation-sensitive imaging layer.

At least one of the above and other features and advantages may also be realized by providing an organosilane-based polymer including a structure represented by T1, a structure represented T2, and a structure represented by T3:

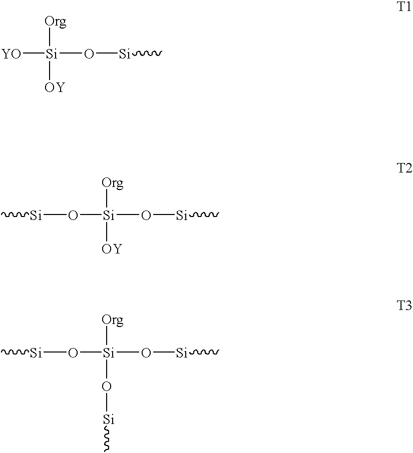

wherein, in T1, T2, and T3 Y is H or a C1 to C6 alkyl group, -Org is —(CH₂)ₙR², a functional group represented by the following Chemical Formula A, —R⁷—Si[R⁶]₃, —R⁹, or —X—Si[R¹⁰]₃, R² is anthracenyl or naphthyl, R⁶, R⁹, and R¹⁰ are each independently a halogen, a hydroxy group, an alkoxy group, a carboxyl group, an ester group, a cyano group, a haloalkylsulfite group, an alkylamine group, an alkylsilylamine group, or an alkylsilyloxy group, R⁷ is anthracenylene, naphthalenylene, biphenylene (-Ph-Ph-), terphenylene (-Ph-Ph-Ph-), or quaterphenylene (-Ph-Ph-Ph-Ph-), and X is a substituted or unsubstituted linear alkylene group, a substituted or unsubstituted branched alkylene group, or an alkylene group including an alkenylene group, an alkynylene group, a heterocyclic group, a urea group, or an isocyanurate group in its main chain,

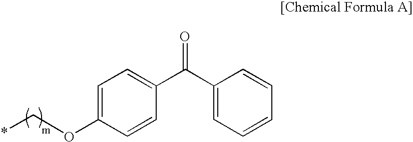

wherein, in Chemical Formula A, m is 1 to 10 and wherein the -Org of at least one of T1, T2, and T3 is —(CH₂)ₙR², the functional group represented by Chemical Formula A, or —R⁷—Si[R⁶]₃ and the -Org of at least one of T1, T2, and T3 is —R⁹ or —X—Si[R¹⁰]₃.

### DETAILED DESCRIPTION

Korean Patent Application No. 10-2008-0137420, filed on Dec. 30, 2008, in the Korean Intellectual Property Office, and entitled: “Resist Underlayer Composition and Method of Manufacturing Integrated Circuit Devices Using Same,” is incorporated by reference herein in its entirety.

Example embodiments will now be described more fully hereinafter; however, they may be embodied in different forms and should not be construed as limited to the embodiments set forth herein. Rather, these embodiments are provided so that this disclosure will be thorough and complete, and will fully convey the scope of the invention to those skilled in the art.

It will be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

Exemplary embodiments will hereinafter be described in detail.

The resist underlayer composition according to an embodiment may include, e.g., a solvent and an organosilane-based polymer, i.e., an organosilane-based polymerization product of at least one first compound represented by the following Chemical Formulae 1 to 3 and at least one second compound represented by Chemical Formulae 4 and 5. In other words, the first compound may include a compound represented by Chemical Formula 1, a compound represented by Chemical Formula 2, and/or a compound represented by Chemical Formula 3 and the second compound may include a compound represented by Chemical Formula 4 and/or a compound represented by Chemical Formula 5.

[R¹]₃Si—(CH₂)ₙR² [Chemical Formula 1]

In the above Chemical Formula 1, each R¹ may independently be, e.g., a halogen, a hydroxyl group, an alkoxy group, a carboxyl group, an ester group, a cyano group, a haloalkylsulfite group, an alkylamine group, an alkylsilylamine group, or an alkylsilyloxy group. In the above Chemical Formula 1, n may be 0 to 5. In the above Chemical Formula 1, R² may be, e.g., anthracenyl or naphthyl.

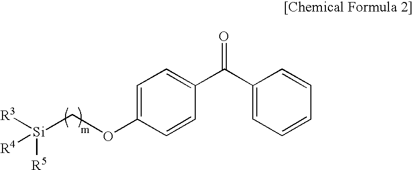

In the above Chemical Formula 2, R³, R⁴, and R⁵ may each independently be, e.g., a halogen, a hydroxy group, an alkoxy group, a carboxyl group, an ester group, a cyano group, a haloalkylsulfite group, an alkylamine group, an alkylsilylamine group, or an alkylsilyloxy group. In the above Chemical Formula 2, m may be 1 to 10.

[R⁶]₃Si—R⁷—Si[R⁶]₃ [Chemical Formula 3]

In the above Chemical Formula 3, each R⁶ may independently be, e.g., a halogen, a hydroxy group, an alkoxy group, a carboxyl group, an ester group, a cyano group, a haloalkylsulfite group, an alkylamine group, an alkylsilylamine group, or an alkylsilyloxy group. In the above Chemical Formula 3, R⁷ may be, e.g., a divalent radical such as anthracenylene, naphthalenylene, biphenylene (-Ph-Ph-), terphenylene (-Ph-Ph-Ph-), or quaterphenylene (-Ph-Ph-Ph-Ph-).

[R⁸]₃Si—R⁹ [Chemical Formula 4]

In the above Chemical Formula 4, each R⁸ may independently be, e.g., a halogen, a hydroxy group, an alkoxy group, a carboxyl group, an ester group, a cyano group, a haloalkylsulfite group, an alkylamine group, an alkylsilylamine group, or an alkylsilyloxy group. In the above Chemical Formula 4, R⁹ may be, e.g., H or a C1 to C6 alkyl group.

[R¹⁰]₃Si—X—Si[R¹⁰]₃ [Chemical Formula 5]

In the above Chemical Formula 5, each R¹⁰ may independently be, e.g., a halogen, a hydroxy group, an alkoxy group, a carboxyl group, an ester group, a cyano group, a haloalkylsulfite group, an alkylamine group, an alkylsilylamine group, or an alkylsilyloxy group. In the above Chemical Formula 5, X may be, e.g., a substituted or unsubstituted linear alkylene group, a substituted or unsubstituted branched alkylene group, or an alkylene group including an alkenylene group, an alkynylene group, a heterocyclic group, an urea group, or an isocyanurate group in its main chain.

In an implementation, the first compound represented by Chemical Formula 2 may be, e.g., an organosilane compound including a diphenylketone group. The organosilane compound including the diphenylketone group may include, e.g., 2-hydroxy-4-(3-triethoxysilylpropoxy)diphenylketone, 2-hydroxy-4-(3-trimethoxysilylpropoxy)diphenylketone, 2-hydroxy-4-(3-trichlorosilylpropoxy)diphenylketone, or a mixture thereof.

In the resist underlayer composition according to an embodiment, the organosilane-based polymer may be obtained by, e.g., hydrolyzing at least one first compound represented by the above Chemical Formulae 1 to 3 and at least one second compound represented by Chemical Formulae 4 and 5, under an acid catalyst or a base catalyst. Then, the hydrolyzed products may be subject to a condensation reaction.

The anthracenylene or anthracenyl group, naphthalenylene or naphthyl group, diphenylketone group, biphenylene (-Ph-Ph-), terphenylene (-Ph-Ph-Ph-), and quaterphenylene (-Ph-Ph-Ph-Ph-) group may have an absorption at a wavelength of, e.g., about 250 nm or less, and may provide a material having high anti-reflective properties. In other words, the anthracenylene or anthracenyl group, naphthalenylene or naphthyl group, diphenylketone group, biphenylene (-Ph-Ph-), terphenylene (-Ph-Ph-Ph-), and quaterphenylene (-Ph-Ph-Ph-Ph-) group may be, e.g., chromophores. A ratio of absorbing groups, i.e., chromophores, in the composition may be controlled by adjusting a content of the first compounds represented by Chemical Formulae 1 to 3. Thus, a resist underlayer composition having desired absorption at a predetermined wavelength and refractive index may be provided.

The organosilane-based polymer may be obtained from a mixture of, e.g., about 0 to about 90 parts by weight of the compound represented by the above Chemical Formula 1, about 0 to about 90 parts by weight of the compound represented by the above Chemical Formula 2, about 0 to about 90 parts by weight of the compound represented by the above Chemical Formula 3, about 0 to about 95 parts by weight of the compound represented by the above Chemical Formula 4, and about 0 to about 95 parts by weight of the compound represented by the above Chemical Formula 5, provided that at least one first compound represented by Chemical Formulae 1 to 3 and at least one second compound represented by Chemical Formulae 4 and 5 are present. In an implementation, the compound represented by the above Chemical Formulae 1 to 3 may be included in an amount of about 0 to about 70 parts by weight, respectively. The mixture may also include, e.g., about 0.001 parts by weight to about 5 parts by weight of an acid or base catalyst and about 50 to about 900 parts by weight of a solvent, based on 100 parts by weight of the at least one first compound represented by Chemical Formulae 1 to 3 and the at least one second compound represented by Chemical Formulae 4 and 5. In an implementation, the at least one first compound represented by Chemical Formulae 1 to 3 may be included in an amount of about 5 to about 90 parts by weight and the at least one second compound represented by the above Chemical Formulae 4 and 5 may be included in an amount of about 10 to about 95 parts by weight. Maintaining the amount of the at least one first compound represented by Chemical Formulae 1 to 3 at about 5 to about 90 parts by weight may help ensure sufficient absorbance and etching selectivity.

The acid catalyst used during the hydrolysis and/or condensation polymerization reaction to obtain the organosilane-based polymer may include, e.g., hydrofluoric acid, hydrochloric acid, bromic acid, iodic acid, nitric acid, sulfuric acid, p-toluene sulfonic acid mono hydrate, diethylsulfate, 2,4,4,6-tetrabromocyclohexadienone, benzoin tosylate, 2-nitrobenzyl tosylate, or alkyl esters of organic sulfonic acids of organic sulfonic acid. The base catalyst may include, e.g., alkylamine such as triethylamine and diethylamine, ammonia, sodium hydroxide, potassium hydroxide, pyridine, or a combination thereof.

The hydrolysis and/or condensation polymerization reaction may be controlled by controlling a kind, amount, and/or addition method of the acid or base catalyst. In an implementation, the acid or base catalyst may be included in an amount of about 0.001 to about 5 parts by weight, based on 100 parts by weight of the at least one first compound represented by Chemical Formula 1 to 3 and the at least one second compound represented by Chemical Formula 4 and 5, in order to obtain a condensation polymerization product having a desired molecular weight.

The organosilane-based polymer may include a structure represented by Chemical Formula 6 (T1), a structure represented by Chemical Formula 7 (T2), and a structure represented by Chemical Formula 8 (T3). In an implementation, the organosilane-based polymer may include about 40 mol % to about 80 mol % of the compound represented by Chemical Formula 7 (T2).

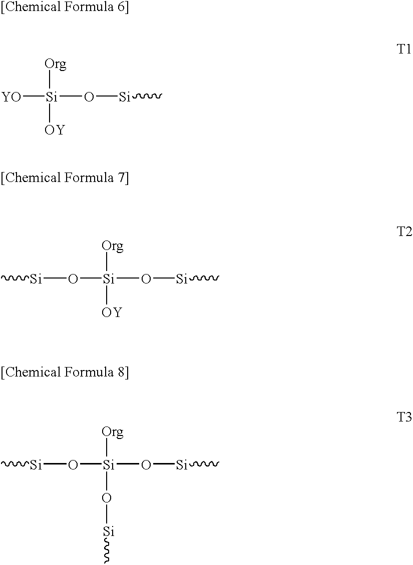

In Chemical Formulae 6 and 7, Y may be, e.g., H or a C1 to C6 alkyl group. In Chemical Formulae 6, 7, and 8, -Org may be —(CH₂)ₙR² (i.e., a residue of Chemical Formula 1), a functional group represented by the following Chemical Formula A (i.e., a residue of Chemical Formula 2), —R⁷—Si[R⁶]₃ (i.e., a residue of Chemical Formula 3), —R⁹ (i.e., a residue of Chemical Formula 4), or —X—Si[R¹⁰]₃ (i.e., a residue of Chemical Formula 5). In Chemical Formulae 6, 7, and 8, R², R⁶, R⁷, R⁹, R¹⁰, and X may be the same as in Chemical Formulae 1 to 5.

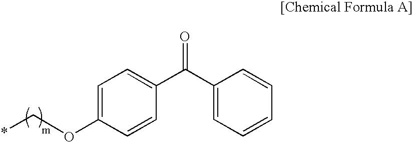

In Chemical Formula A, m may be the same as in Chemical Formula 2, e.g., 1 to 10.

In the organosilane-based polymer, the structures represented by T1 to T3 may be silicon compound structures having three covalent bonds bound with oxygen atoms. The T1 structure may refer to one where one oxygen atom is covalently bound with another silicon, the T2 structure may refer to one where two oxygen atoms are covalently bound with another silicon, and the T3 structure may refer to one where three oxygen atoms are covalently bound with another silicon.

A mole ratio of each of the T1 to T3 structures may be identified by a ²⁹Si NMR analyzer. The organosilane-based polymer may include, e.g., about 40 mol % to about 80 mol % of the structure represented by T2, based on 100 mol % of the T1, T2, and T3 structures. Maintaining the amount of the structure represented by T2 at about 40 mol % to about 80 mol % may help ensure that the organosilane-based polymer has a linear structure as well as relatively large amounts of alkoxy groups and silanol groups, when compared with an organosilane-based polymer including a compound having the T3 structure as a main component. Thus, the organosilane-based polymer of an embodiment may exhibit good coating properties without gelling defects. The organosilane-based polymer of an embodiment may also exhibit high hydrophilicity, compared with a polymer having a greater percentage of the T3 structure, and may be preferably used for multi-layer coating.

In an implementation, the organosilane-based polymer may include, e.g., about 1 mol % to about 30 mol % of the structure represented by T1, about 40 mol % to about 80 mol % of the structure represented by T2, and about 1 mol % to about 50 mol % of the structure represented by T3.

The organosilane-based polymer may have a weight average molecular weight of about 2,000 to about 50,000. Maintaining the weight average molecular weight at about 2,000 to about 50,000 may help ensure good coating and inhibition of undesirable gelling. In an implementation, the organosilane-based polymer may have a weight average molecular weight of about 3,000 to about 20,000.

The organosilane-based polymer may be included in the composition in an amount of about 1 to about 50 parts by weight, based on 100 parts by weight of the composition. Maintaining the amount of the organosilane-based polymer at about 1 to about 50 parts by weight may help ensure good coating. In an implementation, the organosilane-based polymer may be included in an amount of about 1 to about 30 parts by weight, based on 100 parts by weight of the composition.

In the composition, the solvent may be included singularly or as a mixture. The solvent may include, e.g., propylene glycol methyl ether acetate (PGMEA), propylene glycol propyl ether (PGPE), propylene glycol methylether (PGME), methyl isobutyl ketone (MIBK), ethyl lactate, and the like.

The resist underlayer composition may further include at least one additive. The additive may include, e.g., a cross-linking agent, a radical stabilizer, a surfactant, and the like. The cross-linking agent may be selected from the group consisting of melamine resins, amino resins, glycoluril compounds, and bisepoxy compounds.

The resist underlayer composition may further include at least one compound including, e.g., pyridinium p-toluene sulfonate, amidosulfobetain-16, (−)-camphor-10-sulfonic acid ammonium salt, ammonium formate, triethylammonium formate, trimethyammonium formate, tetramethylammonium formate, pyridinium formate, tetrabutylammonium acetate, tetrabutylammonium azide, tetrabutylammonium benzoate, tetrabutylammonium bisulfate, tetrabutylammonium bromide, tetrabutylammonium chloride, tetrabutylammonium cyanide, tetrabutylammonium fluoride, tetrabutylammonium iodide, tetrabutylammonium sulfate, tetrabutylammonium nitrate, tetrabutylammonium nitrite, tetrabutylammonium p-toluenesulfonate, or tetrabutylammonium phosphate. The compound may be, e.g., a cross-linking catalyst, and may promote cross-linking to improve etching resistance and solvent resistance.

The compound, e.g., the cross-linking catalyst, may be added to the composition including the organosilane-based polymerization product and solvent singularly or along with another additive.

The compound, e.g., the cross-linking catalyst, may be included in an amount of about 0.0001 to about 0.1 parts by weight, based on 100 parts by weight of the organosilane-based polymer. Maintaining the amount of the compound at about 0.0001 to about 0.1 parts by weight may help ensure that a cross-linking effect and storage stability are sufficiently obtained.

Another embodiment provides a method of manufacturing a semiconductor integrated circuit device. The method may include, e.g., (a) providing a material layer on a substrate; (b) forming a first resist underlayer using an organic material on the material layer; (c) coating the resist underlayer composition of an embodiment on the first resist underlayer to form a silicon-based second resist underlayer; (d) forming a radiation-sensitive imaging layer on the second resist underlayer; (e) patternwise exposing the radiation-sensitive imaging layer to radiation to form a pattern of radiation-exposed regions in the imaging layer; (f) selectively removing portions of the radiation-sensitive imaging layer and the second resist underlayer to expose portions of the first resist underlayer; (g) selectively removing the patterned second resist underlayer and portions of the first resist underlayer to expose portions of the material layer; and (h) etching the exposed portions of the material layer to pattern the material layer.

The method may further include providing an anti-reflection coating (ARC) between the second resist underlayer and the radiation-sensitive imaging layer.

The method may be used to form a patterned material layer structure, e.g., metal wiring line or a contact hole or bias; an insulation section, e.g., multi-mask trench or shallow trench insulation; or a trench for a capacitor structure, e.g., designing of an integrated circuit device. Also, the method may be used for formation of a patterned layer of, e.g., oxide, nitride, polysilicon, and/or chromium.

The following examples illustrate this disclosure in more detail. However, it is understood that this disclosure is not limited by these examples.

### Example 1

205 g of methyltrimethoxysilane and 200 g of 2-hydroxy-4-(3-triethoxysilylpropoxy)diphenylketone were dissolved in 1000 g of PGMEA in a 3 L 4-neck flask including a mechanical agitator, a condenser, a dropping funnel, and a nitrogen gas introduction tube. Then, 80 g of a 1000 ppm nitric acid aqueous solution was added thereto. Subsequently, the solution was reacted at about 100° C. for about 1 week. After the reaction, a polymer A1 (weight average molecular weight=9500, polydispersity (PD)=4) was obtained.

### Example 2

470 g of bis(triethoxysilyl)ethane and 431 g of 2-hydroxy-4-(3-triethoxysilylpropoxy)diphenylketone were dissolved in 2100 g of PGMEA in a 4 L 4-neck flask including a mechanical agitator, a condenser, a dropping funnel, and a nitrogen gas introduction tube. Then, 139 g of a 1000 ppm nitric acid aqueous solution was added thereto. Subsequently, the solution was reacted at about 90° C. for about 6 days. After the reaction, a polymer A2 (weight average molecular weight=10000, polydispersity (PD)=4) was obtained.

### Example 3

97 g of bis(triethoxysilyl)biphenyl and 157 g of methyltrimethoxy silane were dissolved in 1020 g of PGMEA in a 2 L 4-neck flask including a mechanical agitator, a condenser, a dropping funnel, and a nitrogen gas introduction tube. Then, 60 g of a 1000 ppm nitric acid aqueous solution was added thereto. Subsequently, the solution was reacted at about 50° C. for about 3 days. After the reaction, a polymer B1 (weight average molecular weight=9900, polydispersity (PD)=3) was obtained.

### Example 4

82 g of bis(triethoxysilyl)biphenyl and 173 g of methyltriethoxy silane were dissolved in 1020 g of PGMEA in a 2 L 4-neck flask including a mechanical agitator, a condenser, a dropping funnel, and a nitrogen gas introduction tube. Then, 50 g of a 1000 ppm nitric acid aqueous solution was added thereto. Subsequently, the solution was reacted at about 50° C. for about 8 days. After the reaction, a polymer B2 (weight average molecular weight=9700, polydispersity (PD)=3) was obtained.

### Example 5

75 g of trimethoxysilylanthracene and 375 g of methyltrimethoxy silane were dissolved in 1020 g of PGMEA in a 2 L 4-neck flask including a mechanical agitator, a condenser, a dropping funnel, and a nitrogen gas introduction tube. Then, 60 g of a 1000 ppm nitric acid aqueous solution was added thereto. Subsequently, the solution was reacted at about 70° C. for about 5 days. After the reaction, a polymer C1 (weight average molecular weight=15000, polydispersity (PD)=4) was obtained.

### Example 6

133 g of trimethoxysilyl anthracene, 500 g of bis(triethoxysilyl)methane, and 164 g of methyltrimethoxy silane were dissolved in 2625 g of PGMEA in a 4 L 4-neck flask including a mechanical agitator, a condenser, a dropping funnel, and a nitrogen gas introduction tube. Then, 180 g of a 1000 ppm nitric acid aqueous solution was added thereto. Subsequently, the solution was reacted at about 50° C. for about 4 days. After the reaction, a polymer C2 (weight average molecular weight=9700, polydispersity (PD)=3) was obtained.

### Experimental Example 1

The mole % of structures represented by T1, T2, and T3 in the polymers synthesized according to Examples 1 to 6, respectively, were measured using ²⁹Si NMR spectroscopy (Varian Unity 400). The measurement results are shown in the following Table 1.

TABLE 1

| | T1 (mol %) | T2 (mol %) | T3 (mol %) |
|---|---|---|---|
| Example 1 (A1) | 26 | 40 | 34 |
| Example 2 (A2) | 25 | 53 | 22 |
| Example 3 (B1) | 23 | 48 | 29 |
| Example 4 (B2) | 23 | 50 | 27 |
| Example 5 (C1) | 24 | 61 | 15 |
| Example 6 (C2) | 17 | 65 | 18 |

The results of the Table 1 show that the polymers according to Examples 1 to 6 were organosilane-based polymers including a structure represented by T2 as a main structure.

### Experimental Example 2

Resist underlayer compositions were prepared by mixing 5 g of the polymers synthesized according to Examples 1 to 6, respectively, 0.5 g of pyridinium p-toluenesulfonate as an additive, and 100 g of PGMEA.

Each of the compositions were coated on a wafer and heat treated at about 200° C. for about 1 minute to prepare a film. Then, a refractive index (n) and an extinction coefficient (k) were measured. n and k were measured using Ellipsometer (manufactured by J. A. Woollam), and the results are shown in Table 2.

TABLE 2

| | Optical property | | Optical property | | |
|---|---|---|---|---|---|
| | (193 nm) | | (248 nm) | | |
| | n | k | n | k | |
| | (refractive | (extinction | (refractive | (extinction | Etch rate |
| Sample | index) | coefficient) | index) | coefficient) | (nm/sec) |
| A1 | 1.62 | 0.28 | 1.61 | 0.10 | 0.8 |
| A2 | 1.65 | 0.24 | 1.62 | 0.09 | 0.8 |
| B1 | 1.38 | 0.26 | 1.50 | 0.16 | 0.9 |
| B2 | 1.38 | 0.26 | 1.50 | 0.16 | 0.9 |
| C1 | 1.57 | 0.08 | 1.45 | 0.19 | 0.7 |
| C2 | 1.61 | 0.05 | 1.46 | 0.18 | 0.7 |

The compositions were coated clearly on a wafer without gelling defects. The coating results were a result of the organosilane-based polymers including a structure represented by T2 as a main component.

Six films fabricated using the polymers according to Examples 1 to 6, respectively, exhibited excellent optical properties and different extinction coefficients according to kinds of chromophores included therein. Such results indicate that n and k values may be variously controlled.

### Experimental Example 3

ArF photoresists were coated on the films fabricated according to Experimental Example 2, baked at 110° C. for 60 seconds, exposed to light using an ArF exposure system (S203B Nikon Scanner), and developed using a TMAH (2.38 wt % aqueous solution). The patterns were observed using a field emission scanning electron microscope (FE-SEM). The results show that the underlayer compositions acted as a photoresist underlayer without damage due to photoresist patterning.

### Experimental Example 4

The films fabricated according to Experimental Example 2 were dry-etched using O₂ plasma. The film thicknesses before and after dry-etching were measured and the etch rates were calculated. These results are shown in Table 2. These results show that the film etch rates were 1 nm/sec or less, while acting as good hardmasks.

A silicon oxide layer may be processed using a resist pattern mask. As a circuit becomes finer and a thickness of a resist becomes thinner, a resist may not provide a sufficient mask. A resist underlayer of an embodiment may allow patterning of the oxide layer without damage to the mask.

In particular, the resist pattern may be transferred to the resist underlayer of an embodiment for subsequent processing of the oxide layer. Then, the oxide layer may be subject to dry etching using the resist underlayer as a mask. The underlayer for processing the oxide layer may act as an underlying reflective layer and underlying layer of anti-reflection coating. If the resist underlayer for processing the oxide layer has a similar etching rate to a resist, a mask for processing the underlayer may be included between the resist and the resist underlayer. Accordingly, a multilayer of a first underlayer/a mask for processing the first underlayer (a second underlayer)/a resist may be disposed on the oxide layer.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A resist underlayer composition, comprising:
a solvent; and
an organosilane-based polymer, the organosilane-based polymer being a polymerization product of at least one first compound represented by Chemical Formulae 1 to 3 and at least one second compound represented by Chemical Formulae 4 and 5,
[R¹]₃Si—(CH₂)ₙR² [Chemical Formula 1]
wherein, in the above Chemical Formula 1:
each R¹ is independently a halogen, a hydroxyl group, an alkoxy group, a carboxyl group, an ester group, a cyano group, a haloalkylsulfite group, an alkylamine group, an alkylsilylamine group, or an alkylsilyloxy group,
n is 0 to 5, and
R² is anthracenyl or naphthyl, 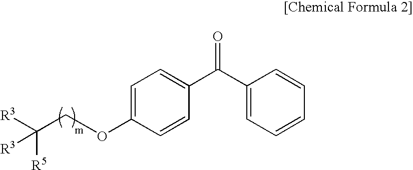
wherein, in the above Chemical Formula 2:
R³, R⁴, and R⁵ are each independently a halogen, a hydroxy group, an alkoxy group, a carboxyl group, an ester group, a cyano group, a haloalkylsulfite group, an alkylamine group, an alkylsilylamine group, or an alkylsilyloxy group, and
m is 1 to 10,
[R⁶]₃Si—R⁷—Si[R⁶]₃ [Chemical Formula 3]
wherein, in the above Chemical Formula 3:
each R⁶ is independently a halogen, a hydroxy group, an alkoxy group, a carboxyl group, an ester group, a cyano group, a haloalkylsulfite group, an alkylamine group, an alkylsilylamine group, or an alkylsilyloxy group, and
R⁷ is anthracenylene, naphthalenylene, biphenylene (-Ph-Ph-), terphenylene (-Ph-Ph-Ph-), or quaterphenylene (-Ph-Ph-Ph-Ph-),
[R⁸]₃Si—R⁹ [Chemical Formula 4]
wherein, in the above Chemical Formula 4:
each R⁸ is independently a halogen, a hydroxy group, an alkoxy group, a carboxyl group, an ester group, a cyano group, a haloalkylsulfite group, an alkylamine group, an alkylsilylamine group, or an alkylsilyloxy group, and
R⁹ is H or a C1 to C6 alkyl group, and
[R¹⁰]₃Si—X—Si[R¹⁰]₃ [Chemical Formula 5]
wherein, in the above Chemical Formula 5:
each R¹⁰ is independently a halogen, a hydroxy group, an alkoxy group, a carboxyl group, an ester group, a cyano group, a haloalkylsulfite group, an alkylamine group, an alkylsilylamine group, or an alkylsilyloxy group,
X is a substituted or unsubstituted linear alkylene group, a substituted or unsubstituted branched alkylene group, or an alkylene group including an alkenylene group, an alkynylene group, a heterocyclic group, a urea group, or an isocyanurate group in its main chain.

2. The resist underlayer composition as claimed in claim 1, wherein the first compound is represented by Chemical Formula 2, the first compound represented by Chemical Formula 2 including at least one of 2-hydroxy-4-(3-triethoxysilylpropoxy)diphenylketone, 2-hydroxy-4-(3-trimethoxysilylpropoxy)diphenylketone, and 2-hydroxy-4-(3-trichlorosilylpropoxy)diphenylketone.

3. The resist underlayer composition as claimed in claim 1, wherein the organosilane-based polymer includes a structure represented by Chemical Formula 6 (T1), about 40 mol % to about 80 mol % of a structure represented by Chemical Formula 7 (T2), and a structure represented by Chemical Formula 8 (T3), 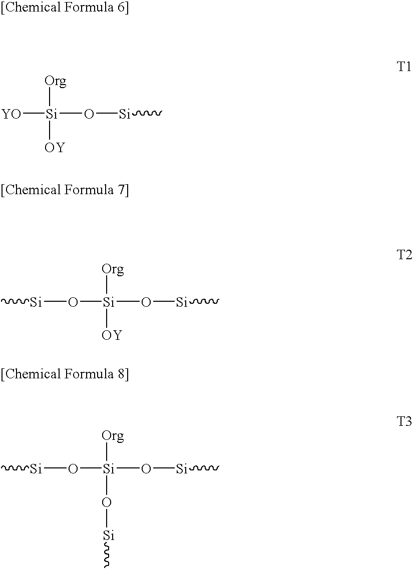
wherein:
in the above Chemical Formulae 6 and 7, Y is H or a C1 to C6 alkyl group,
in the above Chemical Formulae 6, 7, and 8, -Org is —(CH₂)ₙR², a functional group represented by the following Chemical Formula A, —R⁷—Si[R⁶]₃, —R⁹, or —X—Si[R¹⁰]₃, and
in Chemical Formulae 6, 7, and 8, R², R⁶, R⁷, R⁹, R¹⁰, and X are the same as in the above Chemical Formulae 1 to 5, 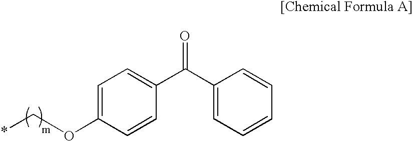
wherein, in the above Chemical Formula A, m is the same as in Chemical Formula 2.

4. The resist underlayer composition as claimed in claim 3, wherein -Org is the functional group represented by Chemical Formula A.

5. The resist underlayer composition as claimed in claim 1, wherein the organosilane-based polymer is included in an amount of about 1 to about 50 parts by weight, based on 100 parts by weight of the composition.

6. The resist underlayer composition as claimed in claim 1, further comprising at least one of a cross-linking agent, a radical stabilizer, and a surfactant.

7. The resist underlayer composition as claimed in claim 1, further comprising at least one of pyridinium p-toluenesulfonate, amidosulfobetain-16, (−)-camphor-10-sulfonic acid ammonium salt, ammonium formate, triethylammonium formate, trimethyammonium formate, tetramethylammonium formate, pyridinium formate, tetrabutylammonium acetate, tetrabutylammonium azide, tetrabutylammonium benzoate, tetrabutylammonium bisulfate, tetrabutylammonium bromide, tetrabutylammonium chloride, tetrabutylammonium cyanide, tetrabutylammonium fluoride, tetrabutylammonium iodide, tetrabutylammonium sulfate, tetrabutylammonium nitrate, tetrabutylammonium nitrite, tetrabutylammonium p-toluenesulfonate, and tetrabutylammonium phosphate.

8. A method of manufacturing a semiconductor integrated circuit device, the method comprising:
providing a material layer on a substrate;
forming a first resist underlayer using an organic material on the material layer;
coating the resist underlayer composition according to claim 1 on the first resist underlayer to form a silicon-based second resist underlayer;
forming a radiation-sensitive imaging layer on the second resist underlayer;
patternwise exposing the radiation-sensitive imaging layer to radiation to form a pattern of radiation-exposed regions in the imaging layer;
selectively removing portions of the radiation-sensitive imaging layer and the second resist underlayer to expose portions of the first resist underlayer;
selectively removing the patterned second resist underlayer and portions of the first resist underlayer to expose portions of the material layer; and
etching the exposed portions of the material layer to pattern the material layer.

9. The method as claimed in claim 8, further comprising providing an anti-reflection coating (ARC) between the second resist underlayer and radiation-sensitive imaging layer.

10. An organosilane-based polymer, comprising:
a structure represented by T1, a structure represented T2, and a structure represented by T3: 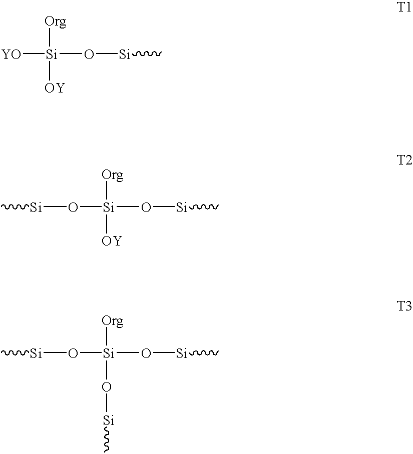
wherein, in T1, T2, and T3:
Y is H or a C1 to C6 alkyl group,
—Org is —(CH₂)ₙR², a functional group represented by the following Chemical Formula A, —R⁷—Si[R⁶]₃, —R⁹, or —X—Si[R¹⁰]₃,
R² is anthracenyl or naphthyl,
R⁶, R⁹, and R¹⁰ are each independently a halogen, a hydroxy group, an alkoxy group, a carboxyl group, an ester group, a cyano group, a haloalkylsulfite group, an alkylamine group, an alkylsilylamine group, or an alkylsilyloxy group,
R⁷ is anthracenylene, naphthalenylene, biphenylene (-Ph-Ph-), terphenylene (-Ph-Ph-Ph-), or quaterphenylene (-Ph-Ph-Ph-Ph-), and
X is a substituted or unsubstituted linear alkylene group, a substituted or unsubstituted branched alkylene group, or an alkylene group including an alkenylene group, an alkynylene group, a heterocyclic group, a urea group, or an isocyanurate group in its main chain, 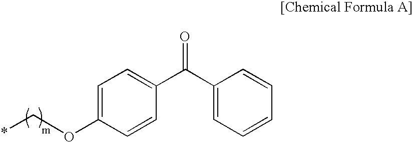
wherein, in Chemical Formula A, m is 1 to 10, and
wherein the -Org of at least one of T1, T2, and T3 is —(CH₂)ₙR², the functional group represented by Chemical Formula A, or —R⁷—Si[R⁶]₃ and the -Org of at least one of T1, T2, and T3 is —R⁹ or —X—Si[R¹⁰]₃.
